(19) United States
(12) Patent Application Publication
(10) Pub. No.: US 2022/0201834 A1
(43) Pub. Date: Jun. 23, 2022

(54) IN-VEHICLE ELECTRONIC DEVICE

(71) Applicant: DENSO CORPORATION, Kariya-city (JP)

(72) Inventors: Toru KOIKE, Kariya-city (JP); Seishin MIKAMI, Kariya-city (JP)

(21) Appl. No.: 17/671,352

(22) Filed: Feb. 14, 2022

Related U.S. Application Data
(63) Continuation of application No. PCT/JP2020/034431, filed on Sep. 11, 2020.

(30) Foreign Application Priority Data
Sep. 12, 2019 (JP) 2019-166484

(51) Int. Cl. H05K 1/02; H05K 5/00; H01Q 1/32

(52) U.S. Cl. CPC H05K 1/021; H01Q 1/325; H05K 5/003

(57) ABSTRACT

An in-vehicle electronic device includes an electronic component and a latent heat storage material. The latent heat storage material contacts the electronic component either directly or indirectly through a heat transfer member. A phase transition temperature of the latent heat storage material is between: a temperature, which is to be reached at night under a circumstance the latent heat storage material is used; and an operating upper limit temperature of the electronic component.

### CROSS REFERENCE TO RELATED APPLICATIONS

This application is a continuation application of International Patent Application No. PCT/JP2020/034431 filed on Sep. 11, 2020, which designated the U.S. and claims the benefit of priority from Japanese Patent Application No. 2019-166484 filed on Sep. 12, 2019. The entire disclosures of all of the above applications are incorporated herein by reference.

### TECHNICAL FIELD

The present disclosure relates to an in-vehicle electronic device, which includes an electronic component, and particularly to a technique that limits a temperature increase of the electronic component.

### BACKGROUND

In a vehicle, the electronic device is often placed in a low temperature part of a vehicle cabin, such as an inside of an instrument panel, which is not easily affected by direct sunlight. In the case where the electronic device is placed in the low temperature part of the vehicle cabin, the temperature of the electronic component is less likely to increase beyond the allowable temperature thereof.

However, it may be necessary to place the electronic component in an area that gets hot in the vehicle. For example, a previously proposed vehicle-mounted antenna device, which is installed to a roof of a vehicle, has a heat transfer member, which has high thermal conductivity and is placed between a circuit section and a housing to facilitate release of the heat to an outside.

### SUMMARY

This section provides a general summary of the disclosure, and is not a comprehensive disclosure of its full scope or all of its features.

According to the present disclosure, there is provided an in-vehicle electronic device that includes an electronic component and a latent heat storage material. The latent heat storage material contacts the electronic component either directly or indirectly. A phase transition temperature of the latent heat storage material is between: a temperature, which is to be reached at night under a circumstance the latent heat storage material is used; and an operating upper limit temperature of the electronic component.

### BRIEF DESCRIPTION OF DRAWINGS

The drawings described herein are for illustrative purposes only of selected embodiments and not all possible implementations, and are not intended to limit the scope of the present disclosure.

FIG. 1 is a cross-sectional view of an in-vehicle electronic device according to a first embodiment.

FIG. 2 is a cross-sectional view of an in-vehicle electronic device according to a second embodiment.

FIG. 3 is a cross-sectional view of an in-vehicle electronic device according to a third embodiment.

FIG. 4 is a cross-sectional view of an in-vehicle electronic device according to a fourth embodiment.

FIG. 5 is a perspective view of a container.

FIG. 6 is a cross-sectional view of an in-vehicle electronic device according to a fifth embodiment.

FIG. 7 is a cross-sectional view of an in-vehicle electronic device according to a sixth embodiment.

FIG. 8 is a cross-sectional view of an in-vehicle electronic device according to a seventh embodiment.

FIG. 9 is a cross-sectional view of an in-vehicle electronic device according to an eighth embodiment.

### DETAILED DESCRIPTION

In a vehicle, an electronic device is often placed in a low temperature part of a vehicle cabin, such as an inside of an instrument panel, which is not easily affected by direct sunlight. In the case where the electronic device is placed in the low temperature part of the vehicle cabin, the temperature of the electronic component is less likely to increase beyond the allowable temperature thereof.

However, it may be necessary to place the electronic component in an area that gets hot in the vehicle. For example, a previously proposed vehicle-mounted antenna device, which is installed to a roof of a vehicle, has a heat transfer member, which has high thermal conductivity and is placed between a circuit section and a housing to facilitate release of the heat to an outside.

However, even if the heat conductive member, which facilitates the release of the heat from the circuit section, is provided, the temperature of the electronic component may exceed an operating upper limit temperature in some cases.

According to the present disclosure, there is provided an in-vehicle electronic device including: an electronic component; and a latent heat storage material that contacts the electronic component either directly or indirectly through a heat transfer member. A phase transition temperature of the latent heat storage material is between: a temperature, which is to be reached at night under a circumstance the latent heat storage material is used; and an operating upper limit temperature of the electronic component.

This in-vehicle electronic device includes the latent heat storage material. The phase transition temperature of the latent heat storage material is between: the temperature, which is to be reached at night; and the operating upper limit temperature of the electronic component. Therefore, in the daytime, when the vehicle is irradiated with the solar heat, the temperature of the in-vehicle electronic device increases. When the temperature of the latent heat storage material reaches the phase transition temperature, a heat energy, which is applied to the in-vehicle electronic device, is used as an energy for the phase transition.

Since the portion of the heat energy, which is applied to the in-vehicle electronic device, is used as the energy for the phase transition, it is possible to limit an increase in the temperature of the electronic component of the in-vehicle electronic device to the phase transition temperature or higher. Since the phase transition temperature is lower than the operating upper limit temperature of the electronic component, the temperature of the electronic component is limited from exceeding the operating upper limit temperature.

Hereinafter, embodiments will be described with reference to the drawings.

### First Embodiment

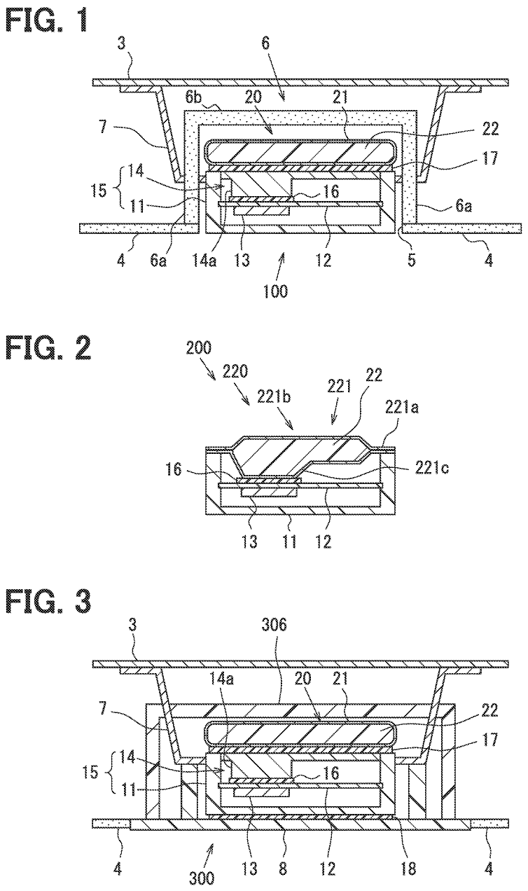

FIG. 1 is a cross-sectional view of an in-vehicle electronic device 100 of a first embodiment.

(Structure of a Portion that Receives the In-Vehicle Electronic Device 100)

The in-vehicle electronic device 100 is located on an inner side of a roof plate 3 of a vehicle 2. The roof plate 3 is an example of the upper outer plate. The upper outer plate is a plate that forms an upper outer surface of the vehicle 2 and is directly irradiated with sunlight from above.

A hole 5 is formed in a lining sheet 4 at a ceiling of a vehicle cabin, and the in-vehicle electronic device 100 is received in the hole 5. The hole 5 is shaped in a rectangular form. The lining sheet 4 is a member that forms the ceiling of the vehicle cabin, and the lining sheet 4 is one of interior materials of the vehicle 2. A lower surface of the in-vehicle electronic device 100 is located at substantially the same position as a lower surface of the lining sheet 4. The lining sheet 4 is provided with a plate having a hardness that can maintain a shape of the ceiling of the vehicle cabin, and a material, such as a cloth, which has a higher heat insulating property than metal, i.e., a thermal insulation material is laminated to the plate on the vehicle cabin side of the plate.

The hole 5, which is formed in the lining sheet 4, penetrates through the lining sheet 4 in a thickness direction of the lining sheet 4. A receiving case 6 is coupled to this hole 5. The receiving case 6 includes a peripheral wall 6a and an upper wall 6b. A lower side of the receiving case 6 is open, but an upper side of the receiving case 6 is closed by the upper wall 6b.

The receiving case 6 has a plate material, which maintains a shape of the receiving case 6, and a thermal insulation material that is laminated to the plate material on the vehicle cabin side of the plate material. A material of a vehicle cabin side surface of the receiving case 6 may be the same as the material of the vehicle cabin side surface of the lining sheet 4. Alternatively, the lining sheet 4 may be recessed toward the roof plate 3 to form the receiving case 6.

A spaced portion of a reinforcement 7, which is spaced away from the roof plate 3, penetrates through the peripheral wall 6a of the receiving case 6. The in-vehicle electronic device 100 is supported by a portion of the reinforcement 7 which is located at an inside of the receiving case 6. The in-vehicle electronic device 100 may be fixed to a different member, such as the receiving case 6 which is different from the reinforcement 7.

### (Structure of the In-Vehicle Electronic Device 100)

The in-vehicle electronic device 100 includes a housing main body 11. The housing main body 11 receives a circuit board 12 and one or more electronic components 13. The housing main body 11 is made of resin. The housing main body 11 is shaped in a bottomed box form having an opening at an upper side thereof. Furthermore, the housing main body 11 may have, for example, a rectangular form in a plan view seen from the upper side of the housing main body 11.

The circuit board 12 is made of resin, such as glass epoxy resin. The electronic component 13 is fixed to a lower surface of the circuit board 12. The circuit board 12 is fixed to the housing main body 11 with, for example, screws. The electronic component 13 is, for example, an integrated circuit (IC) having a function as a circuit of an in-vehicle radio (radio communication device). Although the electronic component 13 is indicated by a laterally extending form in the drawing for the convenience of illustration, a plurality of spatially separated electronic components 13 may be fixed to the circuit board 12. The electronic component 13 may include what can be called an electronic circuit element. The electronic component 13 is fixed to the circuit board 12 by soldering. An operating upper limit temperature is set for the electronic component 13. The operating upper limit temperature can be checked with reference to a catalog or the like. The operating upper limit temperature of the electronic component 13 is, for example, 70° C., 80° C. or the like.

The housing lid 14 is shaped in a form that closes the opening of the housing main body 11. The housing main body 11 and the housing lid 14 cooperate together to form a housing 15. An opposing portion of the housing lid 14, which is opposed to the electronic component 13 through the circuit board 12, is shaped in a form of projection that projects from the rest of the housing lid 14 toward the electronic component 13. This portion will be referred to as a projection 14a of the housing lid 14.

The projection 14a of the housing lid 14 contacts the circuit board 12 through a heat transfer sheet 16. The housing lid 14, which is shaped in an above-described manner, can be manufactured by die-casting of, for example, aluminum or the like. The housing lid 14 forms a portion of a heat transfer path that conducts heat of the electronic component 13 to the latent heat storage unit 20. Therefore, the housing lid 14 is made of a material, such as metal, which has good thermal conductivity.

The heat transfer sheet 16 is made of a material with a better thermal conductivity than air and is deformable by applying pressure thereto. For example, the heat transfer sheet 16 can be made of silicone. Furthermore, the heat transfer sheet 16 can be made of a non-silicone material (i.e., a material other than silicone). Also, in place of the heat transfer sheet 16, heat transfer grease may be used.

The circuit board 12 has a plurality of via holes, which penetrate through the circuit board 12 in a thickness direction of the circuit board 12 to facilitate transfer of the heat of the electronic component 13 to an opposite side of the circuit board 12 which is opposite to the electronic component 13.

The latent heat storage unit 20 is arranged on the upper surface of the housing lid 14 through a heat transfer sheet 17. Like the heat transfer sheet 16, the heat transfer sheet 17 is made of a material which has better thermal conductivity than the air and is deformable by application of pressure thereto. The material of the heat transfer sheet 17 may be the same as the material of the heat transfer sheet 16 or may be different from the material of the heat transfer sheet 16. The heat transfer sheet 17 is an example of a heat transfer member. In place of the heat transfer sheet 17, heat transfer grease may be used as the heat transfer member.

The latent heat storage unit 20 is formed by receiving the latent heat storage material 22 in a container 21. The container 21 is made of a material which has better thermal conductivity than the air. The container 21 is also an example of the heat transfer member. The container 21 is made of, for example, aluminum or the like. The container 21 is formed as a sealed structure after the latent heat storage material 22 is received in the container 21. The container 21 may be formed as follows. Specifically, for example, two box-shaped members, each of which has an opening at one side thereof, are formed by press molding. Thereafter, the latent heat storage material 22 is received in an inside of these box-shaped members that are combined together after installation of the latent heat storage material 22 therein, and these box-shaped members are joined together by brazing.

The container 21 is shaped in a flat form. Specifically, the container 21 is shaped in an elongated form, in which a length measured in a longitudinal direction thereof and a width measured in a lateral direction thereof are longer than a thickness measured in a thickness direction thereof. The longitudinal direction is a direction along a plane which is perpendicular to the thickness direction, and the lateral direction is a direction which is perpendicular to the longitudinal direction in the plane. Hereinafter, the plane, which is perpendicular to the thickness direction, will be referred to as a horizontal plane, and a direction which is parallel to the horizontal plane, will be referred to as a horizontal direction. The horizontal plane is the plane which is perpendicular to the thickness direction but is not necessarily perpendicular to the gravity direction.

By configuring the container 21 in the above-described form, it is possible to limit an increase in a thickness of the entire in-vehicle electronic device 100 while ensuring a required volume for receiving the latent heat storage material 22. The shape of the container 21 may be substantially the same as the shape of the housing main body 11 in the plan view seen from the upper side. With this configuration, despite the provision of the latent heat storage unit 20, it is possible to limit an increase in the size of the in-vehicle electronic device 100 in the plan view seen from the upper side, and it is also possible to minimize the thickness of the in-vehicle electronic device 100 measured in the thickness direction.

The phase transition temperature of the latent heat storage material 22 is between: the temperature, which is to be reached at night under the circumstance the latent heat storage material 22 is used; and the operating upper limit temperature of the electronic component 13. Although it depends on the area where the latent heat storage material 22 is used, the temperature usually drops to or below 40° C. at the night. If the operating upper limit temperature of the electronic component 13 is 70° C., the phase transition temperature may be set to a temperature that is higher than 40° C. and lower than 70° C. (for example, 60° C.).

The latent heat storage material 22 may be a material that contains paraffin. The phase transition temperature of the paraffin can be adjusted by controlling the molecular weight of the paraffin. The material of the latent heat storage material 22 is not necessarily limited to the paraffin based material and may be another material such as inorganic salt based material. The latent heat storage material 22, which is the paraffin based material or the inorganic salt based material, undergoes a phase transition between a solid phase and a liquid phase. The latent heat storage material 22, which undergoes the phase transition between the solid phase and the liquid phase, solidifies at the night and melts when the phase transition temperature is reached.

Alternatively, another type of latent heat storage material 22, which undergoes a phase transition from one solid phase to another solid phase, may be used. Examples of the latent heat storage material 22, which stores heat by the phase transition between the one solid phase and the other solid phase, include polyethylene glycol copolymer cross-linked conjugate, a Fe—Co alloy and the like.

### Conclusion of the First Embodiment

Since the in-vehicle electronic device 100 is located directly below the roof plate 3, the temperature may possibly get high during the daytime. However, the in-vehicle electronic device 100 includes the latent heat storage material 22. The latent heat storage material 22 has the phase transition temperature at which the latent heat storage material 22 solidifies at the night. Therefore, in the daytime, when the vehicle 2 is irradiated with the solar heat, the temperature of the in-vehicle electronic device 100 increases. When the temperature of the latent heat storage material 22 reaches the phase transition temperature, a heat energy, which is applied to the in-vehicle electronic device 100, is used as an energy for the phase transition.

The heat is transferred between the latent heat storage material 22 and the electronic component 13 through a heat transfer path which extends through the container 21, the heat transfer sheet 17, the housing lid 14, the heat transfer sheet 16 and the circuit board 12. Since these members, which constitute the heat transfer path, have good thermal conductivity, the heat is easily transferred between the latent heat storage material 22 and the electronic component 13.

Therefore, since the heat energy, which is applied to the in-vehicle electronic device 100, is used as the energy for carrying out the phase transition of the latent heat storage material 22, the temperature increase of the electronic component 13 is limited. The phase transition temperature of the latent heat storage material 22 is lower than the operating upper limit temperature of the electronic component 13. Therefore, even in the situation where the temperature of the electronic component 13 is likely to increase beyond the operating upper limit temperature at the time of, for example, parking the vehicle under the scorching sun, the increase of the temperature of the electronic component 13 beyond the operating upper limit temperature is limited. The required amount of the latent heat storage material 22 is determined on the assumption that the temperature of the electronic component 13 becomes high at the time of, for example, parking the vehicle under the scorching sun.

In addition, since the in-vehicle electronic device 100 has the latent heat storage material 22, the heat capacity of the in-vehicle electronic device 100 is increased. Therefore, the amount of heat, which is required for the temperature of the electronic component 13 to reach the operating upper limit temperature, is increased, and the temperature of the electronic component 13 is less likely to reach the operating upper limit temperature.

Furthermore, since it is possible to limit the increase of the temperature of the electronic component 13 beyond the operating upper limit temperature, the size of the in-vehicle electronic device 100 can be reduced in comparison to a case where the temperature increase of the electronic component 13 is limited only by a sensible heat storage. Therefore, the in-vehicle electronic device 100 can be easily installed under the roof plate 3 without projecting downward from the lining sheet 4.

In addition, in the first embodiment, the upper side and the lateral sides of the in-vehicle electronic device 100 are surrounded by the receiving case 6 that has the thermal insulation material. With this configuration, it is possible to reduce the solar heat applied to the in-vehicle electronic device 100. Even in this way, the temperature increase of the electronic component 13 can be limited.

Furthermore, the in-vehicle electronic device 100 is located under the roof plate 3, and the housing 15 is located under the latent heat storage unit 20. Therefore, the housing 15 is located closer to the vehicle cabin than the latent heat storage unit 20. With this arrangement, the heat of the electronic component 13 can be efficiently released to the vehicle cabin.

Furthermore, the housing lid 14, which is the portion of the housing 15 that contacts the latent heat storage unit 20, is made of the metal. With this configuration, even though the latent heat storage unit 20 is located at the outside of the housing 15, the heat transfer between the electronic component 13 and the latent heat storage unit 20 can be efficiently performed. Furthermore, since the housing main body 11 is made of the resin, the weight of the housing 15 can be reduced as compared with the case where the entire housing 15 is made of metal.

### Second Embodiment

Next, a second embodiment will be described. In the following description of the second and subsequent embodiments, the elements having the same reference signs as those of the preceding embodiment(s) are the same as the elements having the same reference signs in the preceding embodiment(s) unless otherwise specified. Further, when only a part of the structure is described, the embodiment described above can be applied to the other parts of the structure.

FIG. 2 is a cross-sectional view of an in-vehicle electronic device 200 according to a second embodiment. Like the in-vehicle electronic device 100 of the first embodiment, the in-vehicle electronic device 200 is received in the receiving case 6 shown in FIG. 1.

Unlike the in-vehicle electronic device 100, the in-vehicle electronic device 200 does not include the housing lid 14. The container 221 has the function of the housing lid 14. The latent heat storage unit 220 is configured such that the latent heat storage material 22, which is the same as that of the first embodiment, is received in the container 221.

Like the container 21, the container 221 may be formed as follows. Specifically, two box-shaped members are formed by press molding. Thereafter, the latent heat storage material 22 is received in an inside of these box-shaped members that are combined together after installation of the latent heat storage material 22 therein, and these box-shaped members are joined together. The container 221 has a peripheral portion 221a. The peripheral portion 221a is shaped in a form that contacts an entire upper end surface of the housing main body 11 and does not project from the housing main body 11 in the horizontal direction. The material of the container 221 is the same as that of the container 21 of the first embodiment.

A portion of the container 221, which is other than the peripheral portion 221a, is a receiving portion 221b. The latent heat storage material 22 is received in the receiving portion 221b. An opposing portion of the receiving portion 221b, which is opposed to the electronic component 13, forms a projection 221c. The projection 221c projects from the rest of the receiving portion 221b toward the electronic component 13. A lower end of the projection 221c contacts the electronic component 13 through the heat transfer sheet 16 and the circuit board 12.

According to the in-vehicle electronic device 200 of the second embodiment, the container 221 also functions as the housing lid, so that the housing lid 14 of the first embodiment is not required. With this configuration, the thickness of the in-vehicle electronic device 200, which is measured in the thickness direction, can be reduced.

### Third Embodiment

FIG. 3 is a cross-sectional view of an in-vehicle electronic device 300 according to a third embodiment. The structure of the in-vehicle electronic device 300 is the same as that of the in-vehicle electronic device 100. A difference with respect to the in-vehicle electronic device 100 is a location where the in-vehicle electronic device 300 is received.

The in-vehicle electronic device 300 is located between a garnish 8 and the roof plate 3. The garnish 8 is provided in place of the lining sheet 4. Therefore, the garnish 8 is also one example of the interior material.

The garnish 8 is, for example, a case portion of an overhead console. The garnish 8 is made of resin. The garnish 8 and the housing main body 11 of the in-vehicle electronic device 300 contact with each other through a heat transfer sheet 18. A receiving case 306 is also placed between the garnish 8 and the roof plate 3.

Like the receiving case 6 described in the first embodiment, the receiving case 306 receives the in-vehicle electronic device 300. The receiving case 306 is made of a thermal insulation material or is made of the thermal insulation material and a plate material for maintaining a shape of the receiving case 306.

As in the third embodiment, when the in-vehicle electronic device 300 is placed between the garnish 8 and the roof plate 3, the in-vehicle electronic device 300 cannot be seen from the vehicle cabin. Therefore, an aesthetic appearance of the vehicle cabin is improved.

### Fourth Embodiment

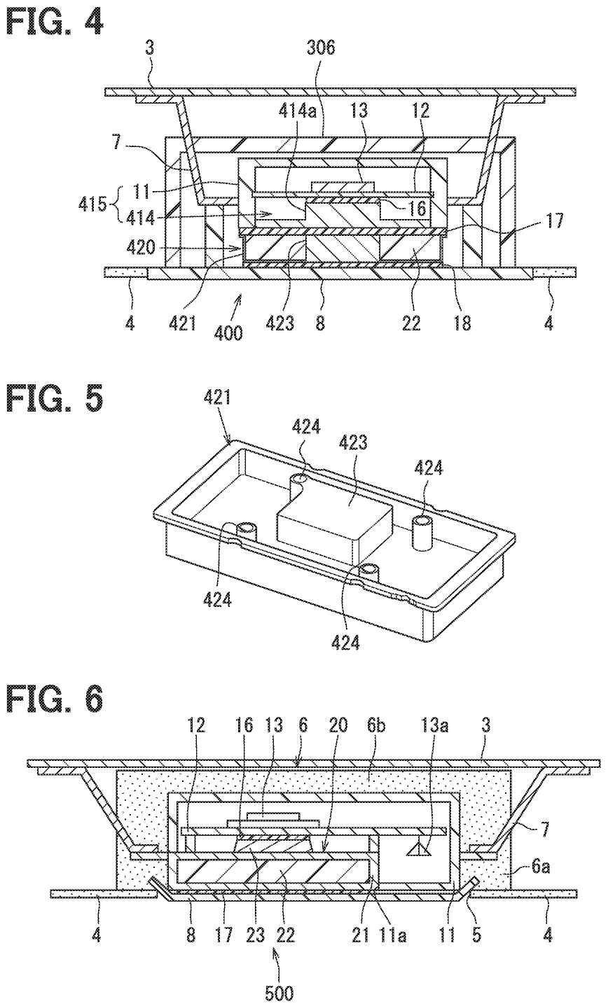

FIG. 4 is a cross-sectional view of an in-vehicle electronic device 400 according to a fourth embodiment. Like the in-vehicle electronic device 300 of the third embodiment, the in-vehicle electronic device 400 is placed between the roof plate 3 and the garnish 8.

Like the preceding embodiments, the in-vehicle electronic device 400 includes the housing main body 11. However, in the in-vehicle electronic device 400, the housing main body 11 has the opening at a lower side of the housing main body 11. Furthermore, in the in-vehicle electronic device 400, the electronic component 13 is located on the upper side of the circuit board 12 and is fixed to a center of an upper surface of the circuit board 12.

Like the housing lid 14 of the first embodiment, a housing lid 414 is made of a material, such as metal, which has good thermal conductivity. Furthermore, like the housing lid 14 of the first embodiment, the housing lid 414 closes the opening of the housing main body 11. However, the projection 414a of the housing lid 414 is formed at the center of the housing lid 414 to correspond to the fact that the electronic component 13 is fixed to the center of the circuit board 12. A distal end of the projection 414a contacts the circuit board 12 through the heat transfer sheet 16. The housing lid 414 and the housing main body 11 cooperate together to form a housing 415.

A latent heat storage unit 420 of the in-vehicle electronic device 400 includes a container 421 having a shape that is different from the shape of the container 21 shown in the previous embodiments. FIG. 5 shows a perspective view of the container 421. The container 421 opens toward the upper side. Furthermore, the container 421 has a heat transfer column 423 at a location that is the center of the container 421 in the horizontal direction, i.e., a location that is directly below the electronic component 13 and the projection 414a of the housing lid 414. The heat transfer column 423 is shaped in a prismatic form. Furthermore, the container 421 has four cylindrical columns 424. Each of the cylindrical columns 424 is a portion through which a bolt for fixing the container 421 to the housing lid 414 is inserted.

The container 421, which includes the heat transfer column 423 and the cylindrical columns 424, is formed integrally in one-piece. Although the heat transfer column 423 is joined to a bottom of the container 421, the bottom of the container 421 and the heat transfer column 423 are formed as a common member, and thereby it is possible to consider that the heat transfer column 423 penetrates through the container 421. The heat transfer column 423 is a heat transfer path member that releases the heat of the electronic component 13 to the vehicle cabin located under the heat transfer column 423.

The latent heat storage material 22 is received in a receiving space of the container 421, which is other than a portion of the container 421 at which the heat transfer column 423 and the cylindrical columns 424 are formed. A lower surface of the container 421 contacts the garnish 8 through the heat transfer sheet 18.

### (Temperature Increase Limiting Effect for the Electronic Component 13 in the Fourth Embodiment)

In the in-vehicle electronic device 400 constructed in the above-described manner, the heat transfer column 423, which is located directly below the electronic component 13, extends through the container 421 in which the latent heat storage material 22 is received. Therefore, a portion of the heat of the electronic component 13 is conducted to the garnish 8, which is exposed in the vehicle cabin, through the heat transfer sheet 16, the housing lid 414, the heat transfer sheet 17, the heat transfer column 423 and the heat transfer sheet 18 each of which has good thermal conductivity. Thus, the heat of the electronic component 13 can be efficiently released into the vehicle cabin that has the relatively low temperature.

Furthermore, since the heat transfer column 423 and the container 421 are integrally formed in one-piece, the assembling work efficiency of the in-vehicle electronic device 400 is improved.

In addition, the in-vehicle electronic device 400 also includes the latent heat storage material 22. The heat can be transferred between the latent heat storage material 22 and the electronic component 13 through the heat transfer sheet 17, the housing lid 414, the heat transfer sheet 16 and the circuit board 12 which form the heat transfer path. The heat transfer sheet 17, the housing lid 414 and the heat transfer sheet 16 are members that have high thermal conductivity. Furthermore, the circuit board 12 has a plurality of via holes which penetrate through the circuit board 12 in the thickness direction of the circuit board 12, and thereby the circuit board 12 can also efficiently conduct the heat in the thickness direction. Therefore, the heat of the electronic component 13 is also efficiently conducted to the latent heat storage material 22. As a result, even in the in-vehicle electronic device 400, the latent heat storage material 22 can also limit the temperature increase of the electronic component 13 beyond the operating upper limit temperature.

### Fifth Embodiment

FIG. 6 is a cross-sectional view of an in-vehicle electronic device 500 according to a fifth embodiment. Like the in-vehicle electronic device 400 of the fourth embodiment, the in-vehicle electronic device 500 is placed between the roof plate 3 and the garnish 8.

Like the preceding embodiments, the in-vehicle electronic device 500 includes the housing main body 11 made of the resin like in the preceding embodiments. The housing main body 11 has an opening 11a that partially opens at the lower side of the housing main body 11. The latent heat storage unit 20 is placed at the inside of the housing main body 11 through the opening 11a.

Furthermore, as shown in FIG. 6, in the in-vehicle electronic device 500, a length of the circuit board 12, which is measured in a vehicle width direction, is longer than a length of the latent heat storage material 22 and a length of the container 21 which are measured in the vehicle width direction. Specifically, in FIG. 6, the circuit board 12 is placed such that a right end of the circuit board 12 projects from a right end of the container 21 toward the right side. In contrast, a left end of the circuit board 12 is placed at a position which is substantially the same as a position of a left end of the container 21.

The electronic component 13 is located on the upper side of the circuit board 12 and is fixed to an upper surface of the circuit board 12. An antenna element 13a is installed to the circuit board 12 of the present embodiment. The antenna element 13a is located on the lower side of the circuit board 12 and is fixed to an end of the lower surface of the circuit board 12. The antenna element 13a is an electronic element that is configured to execute at least one of transmission and reception of a radio wave.

The antenna element 13a is attached to the circuit board 12 as a separate component and projects from the circuit board 12. With this configuration, deterioration of antenna performance caused by the influence of the container 21 and the housing main body 11 can be reduced. The deterioration of the antenna performance means deterioration of antenna radiation pattern performance and/or deterioration of reflection coefficient (return loss) performance at an antenna input end caused by reflection of radio waves from the container 21 and the housing main body 11. It is necessary that a ground of the antenna element 13a is formed on the circuit board 12, and a size of the ground of the antenna element 13a is equal to or larger than ¼ or more of a wavelength A of an operating frequency of the antenna element 13a.

In a case where the antenna ground, the size of which is equal to or larger than ¼ or more of the wavelength A of the operating frequency, cannot be formed, the antenna element 13a and the metal container 21 may be electrically connected with each other at a high frequency, and the container 21 may be used as an antenna ground. Alternatively, the antenna element 13a and the reinforcement 7 may be electrically connected with each other at a high frequency, and the reinforcement 7 may be used as an antenna ground.

Furthermore, even in the case where the antenna ground, the size of which is equal to or larger than ¼ or more of the wavelength A of the operating frequency, cannot be formed, the electrical connection between the circuit board 12 and the container 21 at the high frequency or the electrical connection between the container 21 and the reinforcement 7 at the high frequency is suitable for stabilizing the antenna performance and may be carried out.

The antenna element 13a of the present embodiment is configured to transmit and receive radio waves to and from a communication device located at the inside of the vehicle cabin. Therefore, the antenna element 13a transmits and receives the radio waves based on the corresponding wireless communication standards, such as WiFi (registered trademark) standards or Bluetooth (registered trademark) standards.

A material, such as the container 21 or the latent heat storage material 22, which does not easily transmit the radio waves therethrough, is not arranged in a projected area of the antenna element 13a that is located on the vehicle cabin side of the antenna element 13a. Therefore, with respect to the positional relationship between the antenna element 13a and the latent heat storage unit 20, the location of the antenna element 13a and the location of the latent heat storage unit 20 are displaced from each other in the horizontal direction when they are viewed in the gravity direction. The location of the antenna element 13a and the location of the latent heat storage material 22 do not overlap with each other in the horizontal direction.

In the present embodiment, the latent heat storage unit 20 is located on the lower side of the antenna element 13a. Therefore, it is possible to limit the container 21 of the latent heat storage unit 20 from blocking the radio waves transmitted and received between the communication device in the vehicle cabin and the antenna element 13a.

### Sixth Embodiment

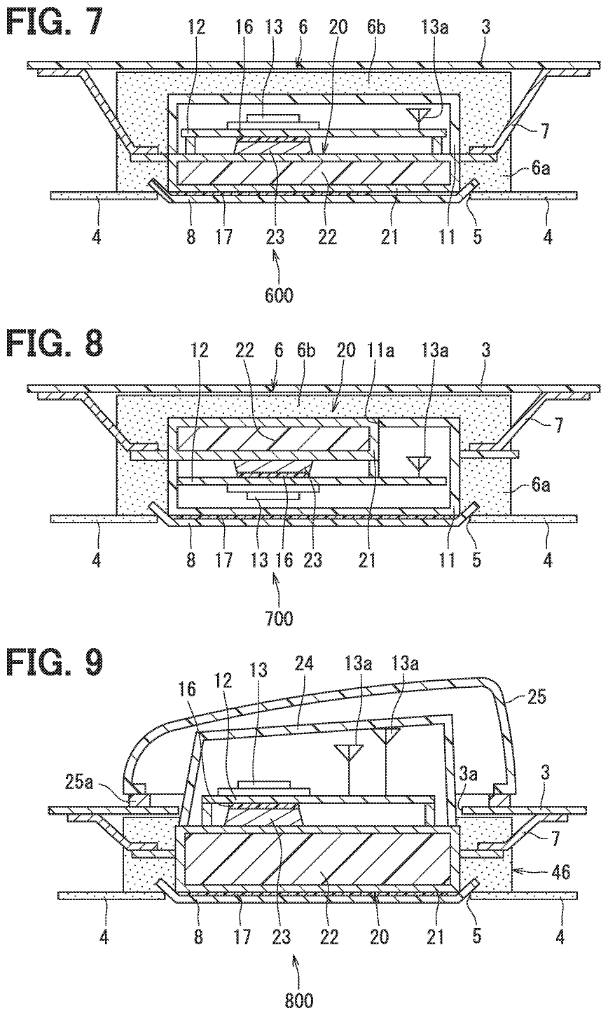

FIG. 7 is a cross-sectional view of an in-vehicle electronic device 600 according to a sixth embodiment. Like the in-vehicle electronic device 400 of the fourth embodiment, the in-vehicle electronic device 600 is placed between the roof plate 3 and the garnish 8. At least a portion of the roof plate 3, which is located on an upper side of the antenna element 13a, has a transmissive portion that is configured to transmit a radio wave through the transmissive portion. The transmissive portion does not need to transmit the radio waves 100% and may partially shield the radio waves as long as it is generally expressed as a radio wave transmissive member. For example, any material, which transmits 90% or more of the radio waves transmitted and received by the antenna element 13a, may be used as the transmissive portion. In the present embodiment, the roof plate 3 is made of a resin material, and the entire roof plate 3 functions as the transmissive portion.

Like the preceding embodiments, the in-vehicle electronic device 600 includes the housing main body 11 made of the resin like in the preceding embodiments. However, even in the in-vehicle electronic device 600, the housing main body 11 has the opening at the lower side of the housing main body 11. The plurality of electronic components 13 are fixed at the upper side of the circuit board 12. Furthermore, the antenna element 13a is also fixed to the upper side of the circuit board 12.

The antenna element 13a of the present embodiment is configured to transmit and receive the radio waves to and from a communication device located at the outside of the vehicle cabin. Therefore, the antenna element 13a transmits and receives radio waves used for, for example, a global navigation satellite system (GNSS) and a public communication network provided by a telecommunications carrier such as an IP network and a mobile telephone network.

A material, such as the roof plate 3 made of the metal or the latent heat storage unit 20, which does not easily transmit the radio waves therethrough, is not arranged in a projected area of the antenna element 13a that is located on the upper side of the antenna element 13a. With respect to the positional relationship between the antenna element 13a and the latent heat storage unit 20, as shown in FIG. 7, the latent heat storage unit 20 is placed at a location which is on the lower side of the antenna element 13a and overlaps with the antenna element 13a in the horizontal direction when they are viewed in the gravity direction.

In the present embodiment, as described above, the latent heat storage unit 20 is located on the lower side of the antenna element 13a. Furthermore, the roof plate 3, which is made of the resin and transmits the radio waves therethrough, is located on the upper side of the antenna element 13a. Therefore, it is possible to limit the container 21 of the latent heat storage unit 20 from blocking the radio waves transmitted and received between the communication facility outside the vehicle and the antenna element 13a.

### Seventh Embodiment

FIG. 8 is a cross-sectional view of an in-vehicle electronic device 700 according to a seventh embodiment. Like the in-vehicle electronic device 400 of the fourth embodiment, the in-vehicle electronic device 700 is placed between the roof plate 3 and the garnish 8. At least a portion of the roof plate 3, which is located on the upper side of the antenna element 13a, has a transmissive portion that is configured to transmit a radio wave through the transmissive portion. In the present embodiment, the roof plate 3 is made of a resin material, and the entire roof plate 3 functions as the transmissive portion.

The in-vehicle electronic device 700 includes the housing main body 11 which is similar to the housing main body 11 of the preceding embodiments. The housing main body 11 has the opening 11a that partially opens at the upper side of the housing main body 11. The latent heat storage unit 20 is placed at the inside of the housing main body 11 through the opening 11a.

Furthermore, as shown in FIG. 8, in the in-vehicle electronic device 700, a size of the circuit board 12 is larger than a size of the latent heat storage material 22 and a size of the container 21. Specifically, the circuit board 12 is placed such that a right end of the circuit board 12 projects from a right end of the container 21 toward the right side.

The electronic component 13 is fixed to a lower surface of the circuit board 12. The antenna element 13a is located on the upper side of the circuit board 12 and is fixed to an end of an upper surface of the circuit board 12.

The antenna element 13a of the present embodiment is configured to transmit and receive the radio waves to and from a communication device located at the inside of the vehicle cabin and a communication device located at the outside of the vehicle cabin. Therefore, a material, such as the roof plate 3 made of the metal or the latent heat storage unit 20, which does not easily transmit the radio waves therethrough, is not arranged in a projected area of the antenna element 13a that is located on the upper side of the antenna element 13a. A material, such as the container 21 or the latent heat storage material 22, which does not easily transmit the radio waves therethrough, is not arranged in a projected area of the antenna element 13a that is located on the vehicle cabin side of the antenna element 13a. Therefore, with respect to the positional relationship between the antenna element 13a and the latent heat storage unit 20, the location of the antenna element 13a and the location of the latent heat storage unit 20 are displaced from each other in the horizontal direction when they are viewed in the gravity direction.

In the present embodiment, as discussed above, the member, which blocks the radio waves, is not located on the upper side and the lower side of the antenna element 13a. Therefore, it is possible to limit the latent heat storage unit 20 from blocking the radio waves transmitted and received between: the communication device inside the vehicle and the communication facility outside the vehicle; and the antenna element 13a.

Furthermore, in the present embodiment, although the antenna element 13a is placed at the upper surface of the circuit board 12, the location of the antenna element 13a is not necessarily limited to the upper surface of the circuit board 12. The antenna element 13a may be placed at the lower surface of the circuit board 12 or may be placed at each of the upper surface and the lower surface of the circuit board 12.

### Eighth Embodiment

FIG. 9 is a cross-sectional view of an in-vehicle electronic device 800 according to an eighth embodiment. An upper portion of the in-vehicle electronic device 800 upwardly projects from the roof plate 3, and a lower side of the in-vehicle electronic device 800 is located on the upper side of the garnish 8. A portion of the roof plate 3 is opened to form an insertion hole 3a, and the space, which is located on the upper side of the garnish 8, is communicated with the outside space, which is located at the outside of the vehicle, through the insertion hole 3a.

The electronic component(s) 13 is fixed at the upper side of the circuit board 12. Furthermore, the antenna elements 13a are also fixed to the upper side of the circuit board 12.

As shown in FIG. 9, a size of the circuit board 12 is smaller than a size of the opening cross-sectional area of the insertion hole 3a, and the circuit board 12 is located on the upper side of the insertion hole 3a, i.e., on the upper side of the roof plate 3. Therefore, the antenna elements 13a are located on the upper side of the roof plate 3. The antenna elements 13a project from the circuit board 12 to a location that is on the upper side of the roof plate 3. The antenna elements 13a are placed at the position where the radio waves can be easily transmitted and received to and from the outside of the vehicle.

The in-vehicle electronic device 800 does not include the housing main body 11 of the preceding embodiments. The in-vehicle electronic device 800 of the present embodiment includes an inner case 24 and an outer case 25, which receive the electronic component(s) 13 and the antenna elements 13a, in place of the housing main body 11. The inner case 24 is a cover member that covers an upper side of the insertion hole 3a. The outer case 25 is a cover member that covers an outer side of the inner case 24. The inner case 24 and the outer case 25 are made of a material, such as a resin material, which transmits radio waves therethrough.

The outer case 25 is sealed and is fixed to the upper surface of the roof plate 3 with an adhesive 25a or the like to have a dustproof and waterproof effect. A gap is formed between an outer surface of the inner case 24 and an inner surface of the outer case 25. This gap is set to a size that implements a heat insulating effect by the air. The gap is set to, for example, 20 mm or less so that convection of the air is unlikely to occur.

As shown in FIG. 9, the latent heat storage unit 20 is located on the lower side of the roof plate 3. The left and right outer sides of the container 21 are covered by a thermal insulation material 46 which has a heat insulating property. Furthermore, a lower surface of the container 21 contacts the garnish 8 through the heat transfer sheet 17.

In the in-vehicle electronic device 800 constructed in the above-described manner, the heat transfer column 23, which is located directly below the electronic component 13, contacts the container 21 in which the latent heat storage material 22 is received. Therefore, a portion of the heat of the electronic component 13 is conducted to the garnish 8, which is exposed to the vehicle cabin, through the heat transfer column 23 and the container 21. Thus, the heat of the electronic component 13 can be efficiently released into the vehicle cabin that has the relatively low temperature.

In the present embodiment, as described above, the latent heat storage material 22 is located on the lower side of the antenna elements 13a. Furthermore, the inner case 24 and the outer case 25, which are made of the resin and transmits the radio waves therethrough, are located on the upper side of the antenna elements 13a. Therefore, it is possible to limit the latent heat storage unit 20 and the roof plate 3 from blocking the radio waves transmitted and received between the communication facility outside the vehicle and the antenna elements 13a.

Furthermore, in the present embodiment, the antenna elements 13a are located on the upper side of the latent heat storage unit 20 but does not need to overlap with the latent heat storage unit 20 at the location which is on the upper side of the latent heat storage unit 20. That is, the antenna elements 13a may be displaced from the latent heat storage unit 20 in the horizontal direction.

Furthermore, in the fifth to eighth embodiments, the antenna element 13a is provided as a separate component. However, the present disclosure should not be limited to such a configuration. The antenna element 13a may be formed as a pattern on the circuit board 12.

Although the embodiments have been described above, the disclosed technology is not limited to the above-described embodiments, and the following modifications are also included in the disclosed scope, and the embodiments may be further modified within the scope of the present disclosure besides the following modifications.

### First Modification

In the above embodiments, the latent heat storage material 22 contacts the electronic component 13 through the circuit board 12. Alternatively, the latent heat storage material 22 may be placed on the same side of the circuit board 12 where the electronic component 13 is placed. In this case, the latent heat storage material 22 contacts the electronic component 13 directly or indirectly through, for example, a heat transfer sheet.

### Second Modification

A plate, which is made of a material having a low emissivity and is mainly made of nickel or aluminum, may be arranged on the surface of the receiving case 6, 306, which is opposed to the roof plate 3.

### Third Modification

The heat transfer column 423 may be formed separately from the container 421. Furthermore, the heat transfer column 423 may be shaped to another form, such as a cylindrical shape, which is different from the prismatic form.

### Fourth Modification

In the above embodiments, the in-vehicle electronic device 100, 200, 300, 400 is located below the roof plate 3. However, the in-vehicle electronic device may be located below a trunk upper plate. Furthermore, when a structure, such as the antenna, which projects outward from the roof plate 3, is installed to the vehicle 2, the in-vehicle electronic device may be located below an upper outer plate of this structure.

### Fifth Modification

In the above embodiments, the container 21 contacts the housing lid 14 through the heat transfer sheet 17. Alternatively, the container 21 may directly contact the housing lid 14. Furthermore, the housing 15 may be entirely made of metal.

What is claimed is:

1. An in-vehicle electronic device comprising:
an electronic component, wherein the in-vehicle electronic device is configured to be located under a roof plate of a vehicle that is an upper outer plate of the vehicle while a thermal insulation material is interposed between the in-vehicle electronic device and the roof plate;
a housing that receives the electronic component;
a latent heat storage material that is located on a lower side of the housing and contacts the electronic component either directly or indirectly through a heat transfer member; and
a heat transfer path member that contacts the housing either directly or indirectly through a heat transfer member, wherein:
the heat transfer path member is located directly below the electronic component and extends through the latent heat storage material; and
a phase transition temperature of the latent heat storage material is between:
a temperature, which is to be reached at night under a circumstance the latent heat storage material is used; and
an operating upper limit temperature of the electronic component.

2. The in-vehicle electronic device of claim 1, comprising a container that receives the latent heat storage material, wherein:
the heat transfer path member is integrally formed in one-piece with the container.

3. An in-vehicle electronic device comprising:
an electronic component, wherein the in-vehicle electronic device is configured to be located under an upper outer plate of a vehicle while a thermal insulation material is interposed between the in-vehicle electronic device and the upper outer plate;
a latent heat storage material that contacts the electronic component either directly or indirectly through a heat transfer member;
a housing main body that receives the electronic component and has an opening; and
a container that receives the latent heat storage material, wherein:
the container closes the opening of the housing main body;
an opposing portion of the container, which is opposed to the electronic component, contacts the electronic component or a circuit board either directly or indirectly through a heat transfer member while the circuit board holds the electronic component; and
a phase transition temperature of the latent heat storage material is between:
a temperature, which is to be reached at night under a circumstance the latent heat storage material is used; and
an operating upper limit temperature of the electronic component.

4. The in-vehicle electronic device according to claim 3, further comprising an antenna element that is configured to execute at least one of transmission and reception of a radio wave.

5. An in-vehicle electronic device comprising:
an electronic component;
a housing that receives the electronic component; and
a latent heat storage material that contacts the electronic component either directly or indirectly through a heat transfer member, wherein:
the latent heat storage material contacts an outer of the housing either directly or indirectly through a heat transfer member;
a portion of the housing, which contacts the latent heat storage material either directly or indirectly through the heat transfer member, is made of metal; and
a phase transition temperature of the latent heat storage material is between:
a temperature, which is to be reached at night under a circumstance the latent heat storage material is used; and
an operating upper limit temperature of the electronic component.

6. The in-vehicle electronic device of claim 5 wherein the in-vehicle electronic device is located under an upper outer plate of a vehicle while a thermal insulation material is interposed between the in-vehicle electronic device and the upper outer plate.

7. The in-vehicle electronic device of claim 6, wherein:
the in-vehicle electronic device is configured to be located under a roof plate of the vehicle that is the upper outer plate while the thermal insulation material is interposed between the in-vehicle electronic device and the roof plate; and
the housing is located on a lower side of the latent heat storage material.

8. An in-vehicle electronic device comprising:
an electronic component;
a latent heat storage material that contacts the electronic component either directly or indirectly through a heat transfer member; and
an antenna element that is configured to execute at least one of transmission and reception of a radio wave, wherein:
a location of the antenna element and a location of the latent heat storage material do not overlap with each other in a horizontal direction; and
a phase transition temperature of the latent heat storage material is between:
a temperature, which is to be reached at night under a circumstance the latent heat storage material is used; and
an operating upper limit temperature of the electronic component.

9. An in-vehicle electronic device comprising:
an electronic component;
a latent heat storage material that contacts the electronic component either directly or indirectly through a heat transfer member; and
an antenna element that is configured to execute at least one of transmission and reception of a radio wave, wherein:
the antenna element is configured to be located under an upper outer plate of a vehicle;
at least a portion of the upper outer plate, which is located on an upper side of the antenna element, has a transmissive portion that is configured to transmit the radio wave through the transmissive portion;
the latent heat storage material is located on a lower side of the antenna element; and
a phase transition temperature of the latent heat storage material is between:
a temperature, which is to be reached at night under a circumstance the latent heat storage material is used; and
an operating upper limit temperature of the electronic component.

10. An in-vehicle electronic device comprising:
an electronic component;
a latent heat storage material that contacts the electronic component either directly or indirectly through a heat transfer member; and
an antenna element that is configured to execute at least one of transmission and reception of a radio wave, wherein:
the antenna element is configured to be located under an upper outer plate of a vehicle;
at least a portion of the upper outer plate, which is located on an upper side of the antenna element, has a transmissive portion that is configured to transmit the radio wave through the transmissive portion;
the latent heat storage material is located on an upper side of the antenna element such that a location of the latent heat storage material and a location of the antenna element do not overlap with each other in a horizontal direction; and
a phase transition temperature of the latent heat storage material is between:
a temperature, which is to be reached at night under a circumstance the latent heat storage material is used; and
an operating upper limit temperature of the electronic component.

11. An in-vehicle electronic device comprising:
an electronic component;
a latent heat storage material that contacts the electronic component either directly or indirectly through a heat transfer member;
an antenna element that is configured to execute at least one of transmission and reception of a radio wave; and
a cover member that receives the antenna element, wherein:
the antenna element is configured to be located above an upper outer plate of a vehicle;
the latent heat storage material is configured to be located under the upper outer plate; and
a phase transition temperature of the latent heat storage material is between:
a temperature, which is to be reached at night under a circumstance the latent heat storage material is used; and
an operating upper limit temperature of the electronic component.
